(19) United States
(12) Patent Application Publication
(10) Pub. No.: US 2026/0047276 A1
(43) Pub. Date: Feb. 12, 2026

(54) DISPLAY PANEL AND ELECTRONIC DEVICE INCLUDING THE SAME

(71) Applicant: Samsung Display Co., Ltd., Yongin-si (KR)

(72) Inventors: Jongwoo JIN, Yongin-si (KR); KIHWAN KIM, Yongin-si (KR); YEONHONG KIM, Yongin-si (KR); JUN HYUNG LIM, Yongin-si (KR)

(73) Assignee: Samsung Display Co., Ltd., Yongin-si (KR)

(21) Appl. No.: 19/276,399

(22) Filed: Jul. 22, 2025

(30) Foreign Application Priority Data
Aug. 12, 2024 (KR) 10-2024-0107509

(51) Int. Cl. H10K 59/121; G06F 3/044; H10D 64/66; H10D 86/40; H10D 86/60; H10K 59/40

(52) U.S. Cl. CPC H10K 59/1213; G06F 3/044; H10D 64/665; H10D 86/423; H10D 86/60; H10K 59/40; G06F 2203/04106

(57) ABSTRACT

A display panel includes a substrate, a light emitting element disposed on the substrate, and a pixel driver connected to the light emitting element. The pixel driver includes a first transistor including a first-first semiconductor pattern, a second-first semiconductor pattern disposed on the first-first semiconductor pattern, and a barrier disposed between the first-first semiconductor pattern and the second-first semiconductor pattern and a second transistor including a first-second semiconductor pattern and a second-second semiconductor pattern disposed on the first-second semiconductor pattern.

### CROSS-REFERENCE TO RELATED APPLICATION(S)

This application claims priority to and benefits of Korean Patent Application No. 10-2024-0107509 under 35 U.S.C. § 119, filed on Aug. 12, 2024 in the Korean Intellectual Property Office, the entire contents of which are incorporated herein by reference.

### BACKGROUND

### 1. Technical Field

Embodiments relate to a display panel and an electronic device including the display panel. More particularly, the embodiments relate to a display panel including a transistor with improved reliability and an electronic device including the display panel.

### 2. Description of Related Art

Multimedia electronic devices, such as televisions, mobile phones, tablet computers, navigation devices, and game devices, include a display panel displaying images. The display panel includes pixels generating the images, and each of the pixels includes a light emitting element generating light and a pixel driver driving the light emitting element.

The pixel driver includes a switching transistor and a driving transistor. The switching transistor has high mobility to have excellent on-off characteristics. The driving transistor has a wide driving range to facilitate grayscale representation.

### SUMMARY

Embodiments provide a display panel including a switching transistor with high mobility and a driving transistor with wide driving range.

Embodiments provide an electronic device including the display panel.

Embodiments provide a display panel including a substrate, a light emitting element disposed on the substrate, and a pixel driver connected to the light emitting element. The pixel driver includes a first transistor including a first-first semiconductor pattern, a second-first semiconductor pattern disposed on the first-first semiconductor pattern, and a barrier disposed between the first-first semiconductor pattern and the second-first semiconductor pattern, and a second transistor including a first-second semiconductor pattern and a second-second semiconductor pattern disposed on the first-second semiconductor pattern.

The first transistor may be a driving transistor, and the second transistor may be a switching transistor.

Each of the first-first semiconductor pattern, the second-first semiconductor pattern, the first-second semiconductor pattern, and the second-second semiconductor pattern may include an oxide semiconductor.

The second-first semiconductor pattern may have an oxygen content greater than an oxygen content of the first-first semiconductor pattern, and the second-second semiconductor pattern may have an oxygen content greater than an oxygen content of the first-second semiconductor pattern.

Each of the first-first semiconductor pattern and the first-second semiconductor pattern may include a crystalline oxide semiconductor.

Each of the first-first semiconductor pattern and the first-second semiconductor pattern may include indium atoms and gallium atoms, and a composition ratio of the indium atoms to the gallium atoms per unit volume may be about 2 or more in both the first-first semiconductor pattern and the first-second semiconductor pattern.

The first-first semiconductor pattern and the second-first semiconductor pattern may have a same composition as each other, and the first-second semiconductor pattern and the second-second semiconductor pattern may have a same composition as each other.

Each of the first-first semiconductor pattern and the first-second semiconductor pattern may have a multi-layer structure formed of different compositions.

The barrier may have a single-layer structure or a multi-layer structure.

The barrier may include a metal layer.

The metal layer may include at least one of titanium, molybdenum, aluminum, copper, tungsten, tantalum, and alloys thereof.

The first transistor may further include a first gate disposed on the second-first semiconductor pattern, and the first gate may be disposed to correspond to the second-first semiconductor pattern in plan view.

The second-first semiconductor pattern and the first gate may be disposed to correspond to the barrier in plan view.

The display panel may further include an insulating layer disposed on the first gate and a connection electrode disposed on the insulating layer. The second-first semiconductor pattern and the first gate may be disposed to overlap a portion of the barrier in plan view, the insulating layer may include a first contact hole and a second contact hole and spaced apart from the first contact hole in plan view, the first contact hole may overlap the barrier and may not overlap the second-first semiconductor pattern and the first gate in plan view, the second contact hole may overlap the barrier, the second-first semiconductor pattern, and the first gate in plan view, and the connection electrode may be connected to the barrier through the first contact hole and connected to the first gate through the second contact hole.

The display panel may further include an insulating layer disposed on the first gate and a connection electrode disposed on the insulating layer. The second-first semiconductor pattern and the first gate may be disposed to overlap a portion of the barrier in plan view, the insulating layer may include a contact hole, a portion of the contact hole may overlap the barrier and may not overlap the second-first semiconductor pattern and the first gate in plan view, another portion of the contact hole may overlap the barrier, the second-first semiconductor pattern, and the first gate in plan view, and the connection electrode may be connected to the barrier and the first gate through the contact hole.

The display panel may further include an inorganic insulating layer disposed on the barrier.

The inorganic insulating layer may include at least one of silicon oxide, silicon nitride, and aluminum oxide.

The second transistor may further include a second gate disposed on the second-second semiconductor pattern, and the second gate may be disposed to correspond to the second-second semiconductor pattern in plan view.

Embodiments provide an electronic device including a substrate, a light emitting element disposed on the substrate, and a pixel driver connected to the light emitting element. The pixel driver includes a first transistor including a first-first semiconductor pattern, a first insulating layer, a barrier including at least one metal layer, a second-first semiconductor pattern, and a first gate, which are sequentially stacked. Each of the first-first semiconductor pattern and the second-first semiconductor pattern includes an oxide semiconductor.

The pixel driver may further include a second transistor including a first-second semiconductor pattern, a second insulating layer, a second-second semiconductor pattern, and a second gate, which are sequentially stacked, and each of the first-second semiconductor pattern and the second-second semiconductor pattern may include an oxide semiconductor.

According to the display panel and the electronic device including the display panel, both the switching transistor with high mobility and the driving transistor with wide driving range are provided, and thus the reliability of the display panel is improved.

### BRIEF DESCRIPTION OF THE DRAWINGS

The above and other advantages of the disclosure will become readily apparent by reference to the following detailed description when considered in conjunction with the accompanying drawings wherein:

FIG. 1 is a schematic perspective view of a display device according to an embodiment;

FIG. 2 is a schematic cross-sectional view of a display device according to an embodiment;

FIG. 3 is a schematic cross-sectional view of a display panel according to an embodiment;

FIG. 4 is a schematic block diagram of a display device according to an embodiment;

FIGS. 5A, 5B, and 5C are schematic diagrams of equivalent circuits of a pixel according to an embodiment;

FIGS. 6A and 6B are schematic cross-sectional views of an area of display panels according to embodiments;

FIGS. 7A, 7B, and 7C are schematic plan views of some components of a circuit element layer according to embodiments; and

FIG. 8 is a schematic plan view of some components of a circuit element layer according to an embodiment.

FIG. 9 is a block diagram of an electronic device according to an embodiment.

FIG. 10 is a schematic view of various electronic devices according to embodiments.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above.” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, a display panel and a display device of the disclosure will be described with reference to accompanying drawings.

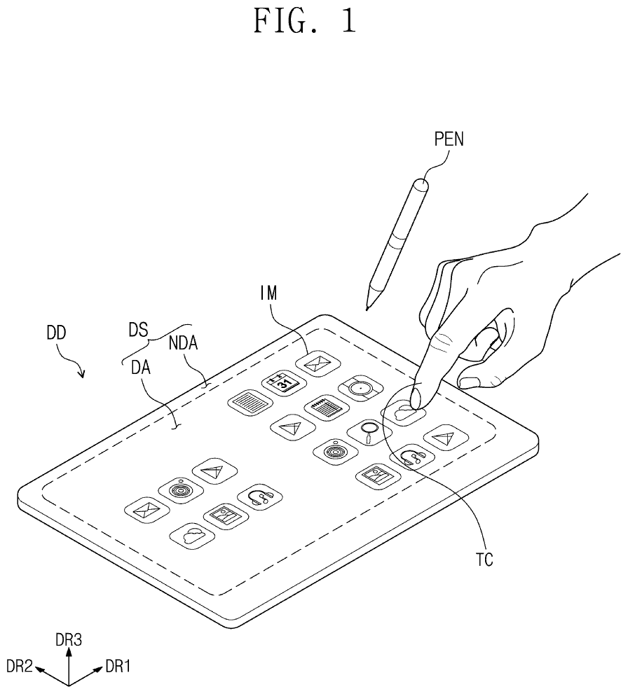

FIG. 1 is a schematic perspective view of a display device DD according to an embodiment.

Referring to FIG. 1, the display device DD may include long sides extending parallel to a first direction DR1 and short sides extending parallel to a second direction DR2 intersecting the first direction DR1.

Hereinafter, a direction substantially perpendicular to a plane defined by the first direction DR1 and the second direction DR2 is referred to as a third direction DR3. In the following descriptions, the expression “when viewed in a plane” or “in plan view” may mean a state of being viewed in the third direction DR3.

A front surface of the display device DD may be defined as a display surface DS and may include the plane defined by the first direction DR1 and the second direction DR2. Images IM generated by the display device DD may be provided to a user through the display surface DS.

The display surface DS may include a display area DA and a non-display area NDA around to the display area DA. The display area DA may be an area through which the images IM are displayed The non-display area NDA may be an area through which the images IM are not displayed. The non-display area NDA may not be defined adjacent to at least one side of the display area DA. In an embodiment, the non-display area NDA may have a frame shape surrounding the display area DA.

The display device DD may sense an external input applied thereto from the outside. For example, the display device DD may sense a first input generated by a touch pen PEN and a second input generated by a touch TC. For example, the touch pen PEN may be defined as an input device, and the display area DA may provide the user with a sensing area where the external input is sensed in addition to displaying the images IM.

The touch pen PEN may be an active pen, an electromagnetic pen, or the like. The second input generated by the touch TC may include various forms, such as a touch input by a user's body part, light, heat, or pressure, but embodiments are not limited thereto. The touch pen PEN may include an active pen, a passive pen, an electromagnetic pen, or the like, however, embodiments are not limited thereto.

The display device DD may be applied to a large-sized electronic device, such as a television set, a monitor, or an outdoor billboard. For example, the display device DD may be applied to a small-sized electronic device and a medium-sized electronic device, such as a personal computer, a notebook computer, a personal digital assistant, a car navigation unit, a game unit, a smartphone, a tablet computer, or a camera. However, these are examples, and the display device DD may be applied to other electronic devices as long as they do not depart from the disclosure.

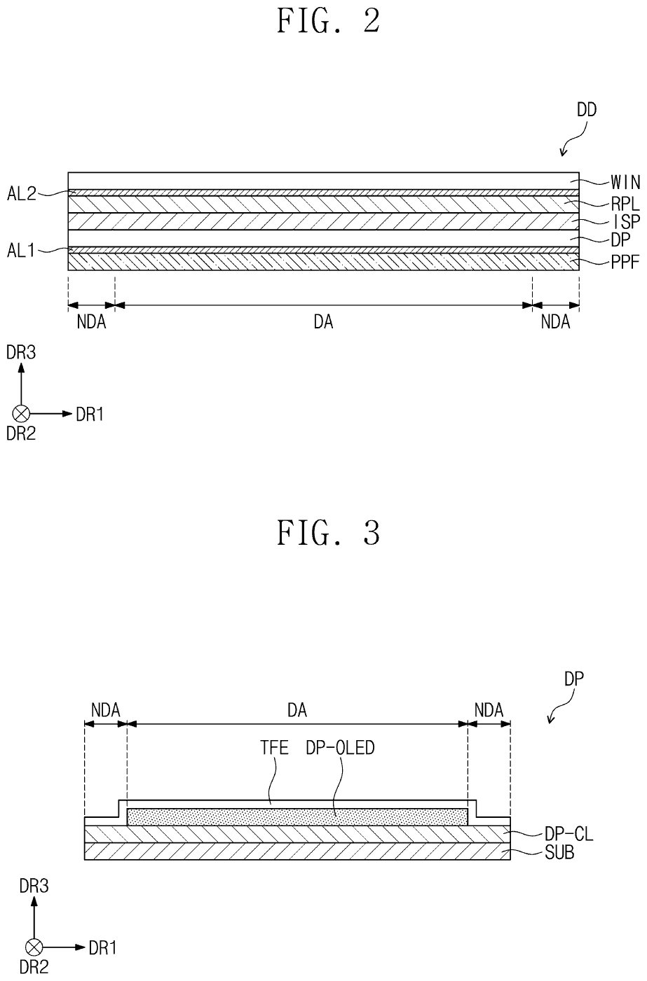

FIG. 2 is a schematic cross-sectional view of the display device DD according to an embodiment. FIG. 3 is a schematic cross-sectional view of a display panel DP according to an embodiment.

Referring to FIG. 2, the display device DD may include a display panel DP, an input sensing unit ISP, an anti-reflective layer RPL, a window WIN, a panel protective film PPF, and first and second adhesive layers AL1 and AL2.

The display panel DP may be a light emitting type display panel. As an example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot or a quantum rod. Hereinafter, the organic light emitting display panel will be described as a representative example of the display panel DP.

Referring to FIG. 3, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include the display area DA and the non-display area NDA around the display area DA. The substrate SUB may include a glass material or a flexible plastic material such as polyimide (PI). The display element layer DP-OLED may be disposed in the display area DA.

Multiple pixels may be disposed in the circuit element layer DP-CL and the display element layer DP-OLED. Each pixel may include a transistor disposed in the circuit element layer DP-CL and a light emitting element disposed in the display element layer DP-OLED and connected to the transistor.

The thin film encapsulation layer TFE may be disposed on the circuit element layer DP-CL to cover the display element layer DP-OLED. The thin film encapsulation layer TFE may protect the pixels from moisture, oxygen, and a foreign substance such as dust particles. According to an embodiment, the thin film encapsulation layer TFE is shown as covering an entire area of the substrate SUB, however, according to an embodiment, the substrate SUB may include some areas that are not covered by the thin film encapsulation layer TFE. According to an embodiment, the exposed areas exposed without being covered by the thin film encapsulation layer TFE may be formed along an edge of the substrate SUB, however, embodiments are not limited thereto or thereby.

The input sensing unit ISP may be disposed on the display panel DP. The input sensing unit ISP may include multiple sensing portions to sense an external input by a capacitive method. The input sensing unit ISP may be manufactured on (e.g., directly on) the display panel DP in case that the display device DD is manufactured. For example, a conductive pattern or an insulating layer that forms the input sensing unit ISP may be disposed (e.g., directly disposed) or patterned on the display panel DP, however, embodiments are not limited thereto or thereby. According to an embodiment, the input sensing unit ISP may be attached to the display panel DP by an adhesive layer after being manufactured separately from the display panel DP.

The anti-reflective layer RPL may be disposed on the input sensing unit ISP. The anti-reflective layer RPL may reduce a reflectance of the display device DD with respect to an external light incident to the display panel DP from outside to improve visibility of the images displayed through the display device DD. The anti-reflective layer RPL may include a retarder, a polarizer, a black matrix, a color filter, or the like, however, embodiments are not limited thereto. The anti-reflective layer RPL may be formed on (e.g., directly on) the input sensing unit ISP through a coating process or a deposition process or may be attached to the input sensing unit ISP by an adhesive layer after being formed as a separate film.

The window WIN may be disposed on the anti-reflective layer RPL. The window WIN may protect the display panel DP, the input sensing unit ISP, and the anti-reflective layer RPL from external scratches and impacts.

The panel protective film PPF may be disposed under the display panel DP. The panel protective film PPF may support the display panel DP and may protect a lower portion of the display panel DP. The panel protective film PPF may have insulating properties. As an example, the panel protective film PPF may include a plastic material such as polyethylene terephthalate (PET), polyimide (PI), and polypropylene (PP).

The first adhesive layer AL1 may be disposed between the display panel DP and the panel protective film PPF. The display panel DP and the panel protective film PPF may be coupled to each other by the first adhesive layer AL1. The second adhesive layer AL2 may be disposed between the window WIN and the anti-reflective layer RPL, and the window WIN and the anti-reflective layer RPL may be coupled to each other by the second adhesive layer AL2.

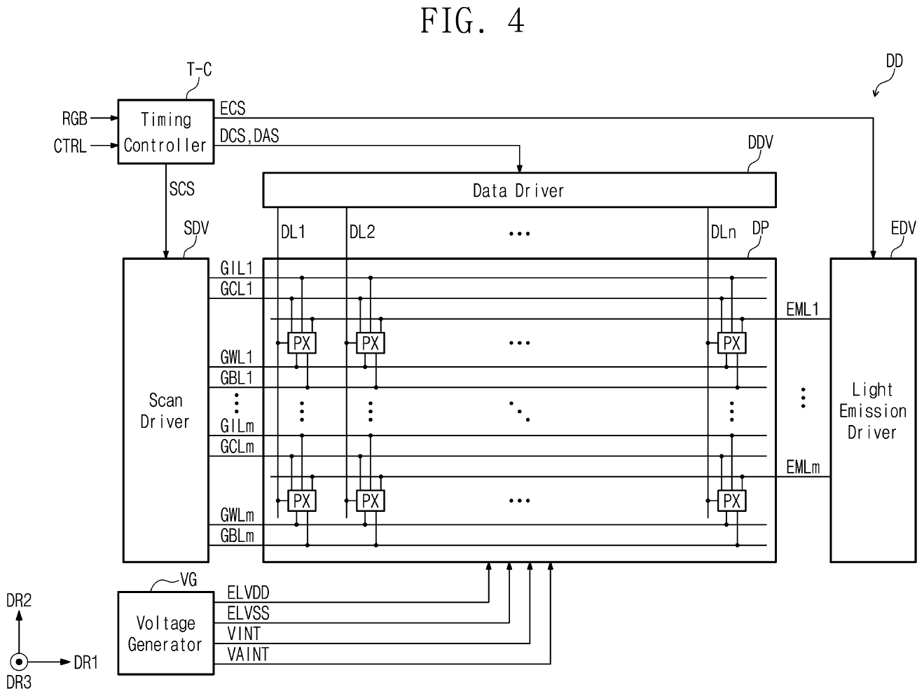

FIG. 4 is a block diagram of the display device DD according to an embodiment.

Referring to FIG. 4, the display device DD may include the display panel DP, a timing controller T-C, a scan driver SDV, a data driver DDV, a light emission driver EDV, and a voltage generator VG.

The display panel DP may include multiple scan lines GIL1 to GILm, GCL1 to GCLm, GWL1 to GWLm, and GBL1 to GBLm, multiple emission lines EML1 to EMLm, multiple data lines DL1 to DLn, and multiple pixels PX. Each of “m” and “n” is a natural number.

The pixels PX may be electrically connected to the scan lines GIL1 to GILm, GCL1 to GCLm, GWL1 to GWLm, and GBL1 to GBLm, the emission lines EML1 to EMLm, the data lines DL1 to DLn. Each of the pixels PX may be electrically connected to four corresponding scan lines, one corresponding data line, and one corresponding emission line.

The scan lines GIL1 to GILm, GCL1 to GCLm, GWL1 to GWLm, and GBL1 to GBLm may include multiple initialization scan lines GIL1 to GILm, multiple compensation scan lines GCL1 to GCLm, multiple write scan lines GWL1 to GWLm, and multiple bias scan lines GBL1 to GBLm.

Each of the pixels PX may be connected to a corresponding initialization scan line among the initialization scan lines GIL1 to GILm, a corresponding compensation scan line among the compensation scan lines GCL1 to GCLm, a corresponding write scan line among the write scan lines GWL1 to GWLm, and a corresponding bias scan line among the bias scan lines GBL1 to GBLm.

The scan lines GIL1 to GILm, GCL1 to GCLm, GWL1 to GWLm, GBL1 to GBLm may be connected to the scan driver SDV, may extend in the first direction DR1, and may be arranged in the second direction DR2. The emission lines EML1 to EMLm may be connected to the light emission driver EDV, may extend in the first direction DR1, and may be arranged in the second direction DR2. The data lines DL1 to DLn may be connected to the data driver DDV, may extend in the second direction DR2, and may be arranged in the first direction DR1.

In an embodiment, the scan driver SDV, the light emission driver EDV, and the data driver DDV may be substantially disposed in the display panel DP. According to an embodiment, at least one of the scan driver SDV, the light emission driver EDV, and the data driver DDV may be electrically connected to the display panel DP after being provided to a separate circuit board, and thus, electrical signals may be provided to the pixels PX.

The timing controller T-C may receive an image signal RGB and control signals CTRL. The timing controller T-C may convert a data format of the image signal RGB to a data format appropriate to an interface between the data driver DDV and the timing controller T-C to generate an image data signal DAS. The timing controller T-C may generate a scan control signal SCS, a data control signal DCS, and a light emission control signal ECS.

The voltage generator VG may generate voltages required to operate the display panel DP. The voltage generator VG may generate a first driving voltage ELVDD, a second driving voltage ELVSS, a first initialization voltage VINT, and a second initialization voltage VAINT. The first driving voltage ELVDD, the second driving voltage ELVSS, the first initialization voltage VINT, and the second initialization voltage VAINT may be applied to the pixels PX.

The scan driver SDV may receive the scan control signal SCS from the timing controller T-C. The scan driver SDV may output scan signals to the scan lines GIL1 to GILm, GCL1 to GCLm, GWL1 to GWLm, and GBL1 to GBLm in response to the scan control signal SCS. The scan signals may be applied to the pixels PX via the scan lines GIL1 to GILm, GCL1 to GCLm, GWL1 to GWLm, and GBL1 to GBLm.

The data driver DDV may receive the data control signal DCS and the image data signal DAS from the timing controller T-C. The data driver DDV may convert the image data signal DAS to data signals and may output the data signals. The data signals may be analog voltages corresponding to grayscale values of the image data signal DAS. The data signals may be applied to the pixels PX via the data lines DL1 to DLn.

The light emission driver EDV may receive the light emission control signal ECS from the timing controller T-C. The light emission driver EDV may output emission signals to the emission lines EML1 to EMLm in response to the light emission control signal ECS. The emission signals may be applied to the pixels PX via the emission lines EML1 to EMLm.

The pixels PX may receive the data voltages in response to the scan signals. The pixels PX may emit a light with luminance corresponding to the data voltages in response to the emission signals to display the images.

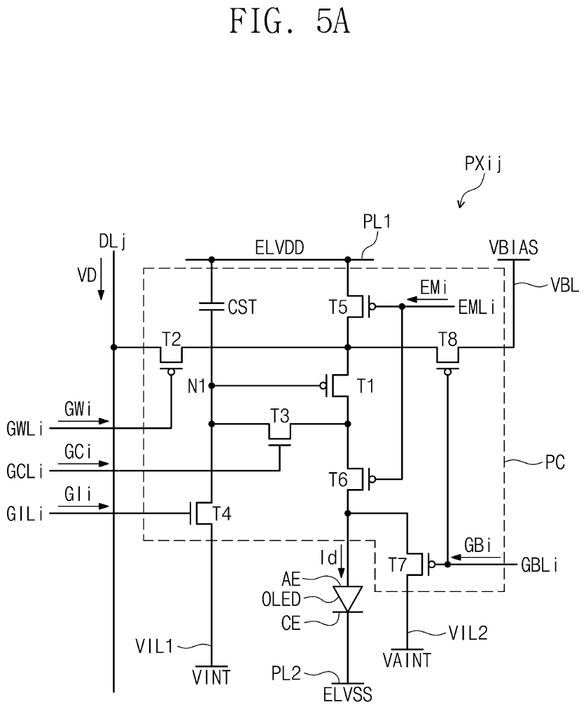

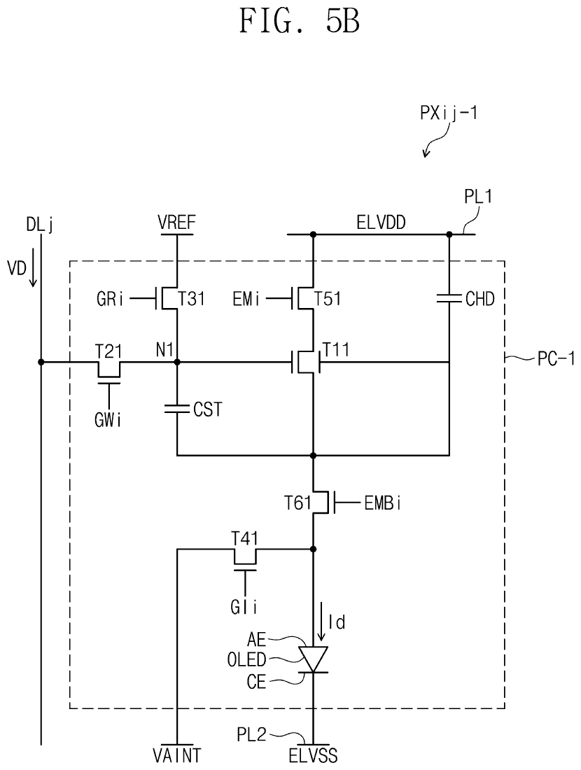

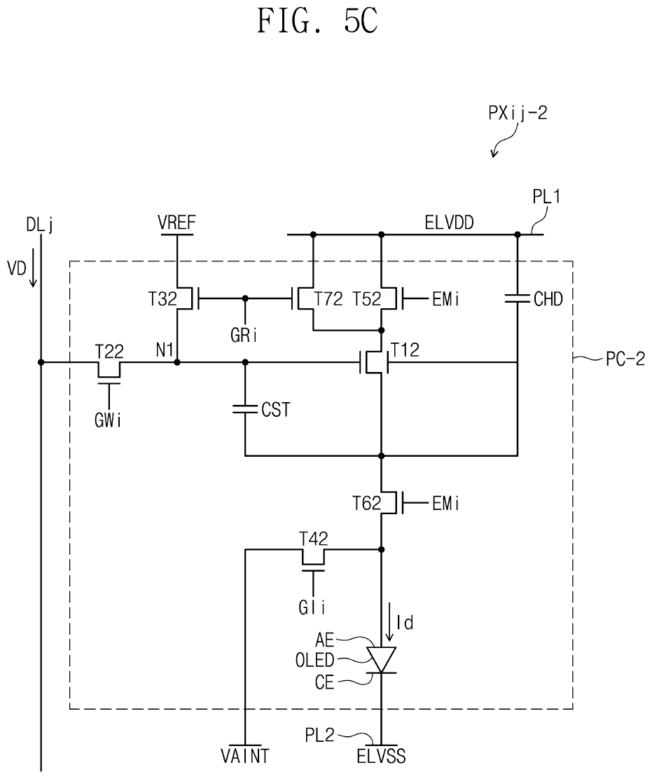

FIGS. 5A, 5B, and 5C are schematic diagrams of equivalent circuits of pixels PXij, PXij-1, and PXij-2 according to an embodiment. FIGS. 5A, 5B, and 5C show the equivalent circuits of one pixel among the pixels shown in FIG. 4.

As an example, FIG. 5A shows the pixel PXij connected to a j-th data line DLj, i-th scan lines GWLi, GCLi, GILi, and GBLi, and an i-th emission line EMLi. Each of “i” and “j” is a natural number.

Referring to FIG. 5A, the pixel PXij may include a pixel driver PC and a light emitting element OLED connected to the pixel driver PC. The light emitting element OLED may be driven by the pixel driver PC.

The pixel driver PC may include multiple transistors T1 to T8 and a capacitor CST. The transistors T1 to T8 and the capacitor CST may control an amount of current Id flowing through the light emitting element OLED. The light emitting element OLED may emit a light with a luminance corresponding to the amount of current Id provided from the pixel driver PC.

The i-th write scan line GWLi may receive an i-th write scan signal GWi, and the i-th compensation scan line GCLi may receive an i-th compensation scan signal GCi. The i-th initialization scan line GILi may receive an i-th initialization scan signal GIi, and the i-th bias scan line GBLi may receive an i-th bias scan signal GBi. The i-th light emission line EMLi may receive an i-th light emission signal EMi.

The pixel PXij may be connected to the j-th data line DLj, the i-th write scan line GWLi, the i-th compensation scan line GCLi, the i-th initialization scan line GILi, the i-th bias scan line GBLi, the i-th emission line EMLi, a first initialization line VIL1, a second initialization line VIL2, a bias line VBL, and first and second power lines PL1 and PL2.

The first initialization line VIL1 may receive the first initialization voltage VINT, and the second initialization line VIL2 may receive the second initialization voltage VAINT. The bias line VBL may receive a bias voltage VBIAS. The first power line PL1 may receive the first driving voltage ELVDD, and the second power line PL2 may receive the second driving voltage ELVSS.

Each of the transistors T1 to T8 may include a source electrode, a drain electrode, and a gate electrode. Hereinafter, for the sake of explanation, one of the source electrode and the drain electrode may be referred to as a first electrode, and the other of the source electrode and the drain electrode may be referred to as a second electrode. For example, the gate electrode may be referred to as a control electrode.

The transistors T1 to T8 may include first, second, third, fourth, fifth, sixth, seventh, and eighth transistors T1, T2, T3, T4, T5, T6, T7, and T8. Each of the first, second, fifth, sixth, seventh, and eighth transistors T1, T2, T5, T6, T7, and T8 may be a PMOS transistor. Each of the third and fourth transistors T3 and T4 may be an NMOS transistor.

The first transistor T1 may be defined as a driving transistor, and the second transistor T2 may be defined as a switching transistor. The third transistor T3 may be defined as a compensation transistor. The fourth transistor T4 and the seventh transistor T7 may be defined as an initialization transistor. The fifth transistor T5 and the sixth transistor T6 may be defined as a light emission control transistor. The eighth transistor T8 may be defined as a bias transistor.

The light emitting element OLED may include an organic light emitting element. The light emitting element OLED may include an anode AE and a cathode CE. The anode AE may receive the first driving voltage ELVDD through the sixth, first, and fifth transistors T6, T1, and T5. The first driving voltage ELVDD may be applied to the pixel driver PC via the first power line PL1.

The cathode CE may receive the second driving voltage ELVSS having a level lower than a level of the first driving voltage ELVDD. The second driving voltage ELVSS may be applied to the pixel driver PC via the second power line PL2.

The first transistor T1 may be disposed between the fifth transistor T5 and the sixth transistor T6 and may be connected to the fifth transistor T5 and the sixth transistor T6. The first transistor T1 may be connected to the first power line PL1 through the fifth transistor T5 and may be connected to the anode AE through the sixth transistor T6.

The first transistor T1 may include the first electrode connected to the first power line PL1 through the fifth transistor T5, the second electrode connected to the anode AE through the sixth transistor T6, and the control electrode connected to a first node N1.

The first electrode of the first transistor T1 may be connected to the fifth transistor T5, and the second electrode of the first transistor T1 may be connected to the sixth transistor T6. The first transistor T1 may control the amount of current Id flowing through the light emitting element OLED based on a voltage of the first node N1, which is applied to the control electrode of the first transistor T1.

The second transistor T2 may be disposed between the first transistor T1 and the j-th data line DLj and may be connected to the first transistor T1 and the j-th data line DLj. The second transistor T2 may include the first electrode connected to the j-th data line DLj, the second electrode connected to the first electrode of the first transistor T1, and the control electrode connected to the i-th write scan line GWLi.

The second transistor T2 may be turned on in response to the i-th write scan signal GWi applied thereto through the i-th write scan line GWLi to electrically connect the j-th data line DLj and the first electrode of the first transistor T1. The second transistor T2 may perform a switching operation to provide a data voltage VD corresponding to the data signal and provided through the j-th data line DLj to the first electrode of the first transistor T1.

The third transistor T3 may be connected to the second electrode of the first transistor T1 and the first node N1. The third transistor T3 may include the first electrode connected to the second electrode of the first transistor T1, the second electrode connected to the first node N1, and the control electrode connected to the i-th compensation scan line GCLi.

The third transistor T3 may be turned on in response to the i-th compensation scan signal GCi applied thereto through the i-th compensation scan line GCLi to electrically connect the second electrode of the first transistor T1 and the control electrode of the first transistor T1. In case that the third transistor T3 is turned on, the first transistor T1 and the third transistor T3 may be connected to each other in a diode configuration.

The fourth transistor T4 may be connected to the first node N1. The fourth transistor T4 may include the first electrode connected to the first node N1, the second electrode connected to the first initialization line VIL1, and the control electrode connected to the i-th initialization scan line GILi. The fourth transistor T4 may be turned on in response to the i-th initialization scan signal GIi applied thereto through the i-th initialization scan line GILi to provide the first initialization voltage VINT from the first initialization line VIL1 to the first node N1.

The fifth transistor T5 may include the first electrode connected to the first power line PL1, the second electrode connected to the first electrode of the first transistor T1, and the control electrode connected to the i-th light emission line EMLi.

The sixth transistor T6 may include the first electrode connected to the second electrode of the first transistor T1, the second electrode connected to the anode AE, and the control electrode connected to the i-th light emission line EMLi.

The fifth transistor T5 and the sixth transistor T6 may be turned on in response to the i-th light emission signal EMi applied thereto through the i-th light emission line EMLi. Due to the turned-on fifth and sixth transistors T5 and T6, the first driving voltage ELVDD may be provided to the light emitting element OLED, and thus, a driving current Id may flow through the light emitting element OLED. Accordingly, the light emitting element OLED may emit a light.

The seventh transistor T7 may include the first electrode connected to the anode AE, the second electrode connected to the second initialization line VIL2, and the control electrode connected to the i-th bias scan line GBLi. The seventh transistor T7 may be turned on in response to the i-th bias scan signal GBi applied thereto through the i-th bias scan line GBLi to provide the second initialization voltage VAINT provided through the second initialization line VIL2 to the anode AE of the light emitting element OLED.

According to an embodiment, the second initialization voltage VAINT may have a level different from that of the first initialization voltage VINT, however, embodiments are not limited thereto or thereby. According to an embodiment, the second initialization voltage VAINT may have substantially the same level as the first initialization voltage VINT.

The seventh transistor T7 may improve a black color representation of the pixel PXij. For example, in case that the seventh transistor T7 is turned on, a parasitic capacitance of the light emitting element OLED may be discharged. Accordingly, in case that implementing a black luminance, the light emitting element OLED does not emit the light due to a leakage current from the first transistor T1, and thus the black color representation may be improved.

The capacitor CST may include a first electrode connected to the first power line PL1 and a second electrode connected to the first node N1. In case that the fifth transistor T5 and the sixth transistor T6 are turned on, an amount of current Id flowing through the first transistor T1 may be determined based on a voltage charged in the capacitor CST.

The eighth transistor T8 may include the first electrode connected to the bias line VBL, the second electrode connected to the first electrode of the first transistor T1, and the control electrode connected to the i-th bias scan line GBLi.

The eighth transistor T8 may be turned on in response to the i-th bias scan signal GBi and may apply the bias voltage VBIAS, which is applied thereto through the bias line VBL, to the first electrode of the first transistor T1.

Referring to FIG. 5B, a pixel driver PC-1 may include six transistors, e.g., first, second, third, fourth, fifth, and sixth transistors T11, T21, T31, T41, T51, and T61, and two capacitors CST and CHD.

The first transistor T11 may function as a driving transistor, and the second transistor T21 may function as a switching transistor.

The third transistor T31 may function as a reset transistor. The third transistor T31 may provide a reference voltage VREF to a first node N1 in response to a reset signal GRi applied thereto from a gate driving circuit. The first node N1 may be reset to the reference voltage VREF, and thus, the influence of residual voltage from a previous stage may be reduced.

The fourth transistor T41 may function as an anode initialization transistor. The fourth transistor T41 may correspond to the seventh transistor T7 shown in FIG. 5A. The fourth transistor T41 may initialize an anode of a light emitting element to a second initialization voltage VAINT in response to an initialization scan signal GIi.

Each of the fifth transistor T51 and the sixth transistor T61 may function as a light emission control transistor. In an embodiment, the fifth transistor T51 and the sixth transistor T61 may be driven in response to different light emission control signals. For example, the fifth transistor T51 may apply a first driving voltage ELVDD to the first transistor T11 in response to a first light emission control signal EMi, and the sixth transistor T61 may be turned on in response to a second light emission control signal EMBi. According to an embodiment, the fifth transistor T51 and the sixth transistor T61 may be turned on or off at different timings, and thus, the fifth transistor T51 and the sixth transistor T61 may be driven independently from each other, however, this is an example. According to an embodiment, the first light emission control signal EMi and the second light emission control signal EMBi may be applied at the same timing, however, embodiments are not limited thereto.

Referring to FIG. 5C, a pixel driver PC-2 may include seven transistors, e.g., first, second, third, fourth, fifth, sixth, and seventh transistors T12, T22, T32, T42, T52, T62, and T72, and two capacitors CST and CHD.

The first transistor T12 may function as a driving transistor, and the second transistor T22 may function as a switching transistor.

The third transistor T32 may function as a reset transistor, and the fourth transistor T42 may function as an anode initialization transistor. Each of the fifth transistor T52 and the sixth transistor T62 may function as a light emission control transistor.

When compared to the pixel driver PC-1 of FIG. 5B, the pixel driver PC-2 may further include the seventh transistor T72. The seventh transistor T72 may be disposed between the first driving voltage ELVDD and a drain electrode of the first transistor T12. The seventh transistor T72 may apply the first driving voltage ELVDD to the first transistor T12 in response to a reset signal GRi. For example, the seventh transistor T72 and the third transistor T32 may be substantially simultaneously turned on at the same timing. For example, the drain electrode of the first transistor T12 may receive the first driving voltage ELVDD at a timing at which a first node N1 is reset.

The sixth transistor T62 may be driven by a first light emission control signal EMi. For example, the sixth transistor T62 and the fifth transistor T52 may be substantially simultaneously turned on at the same timing.

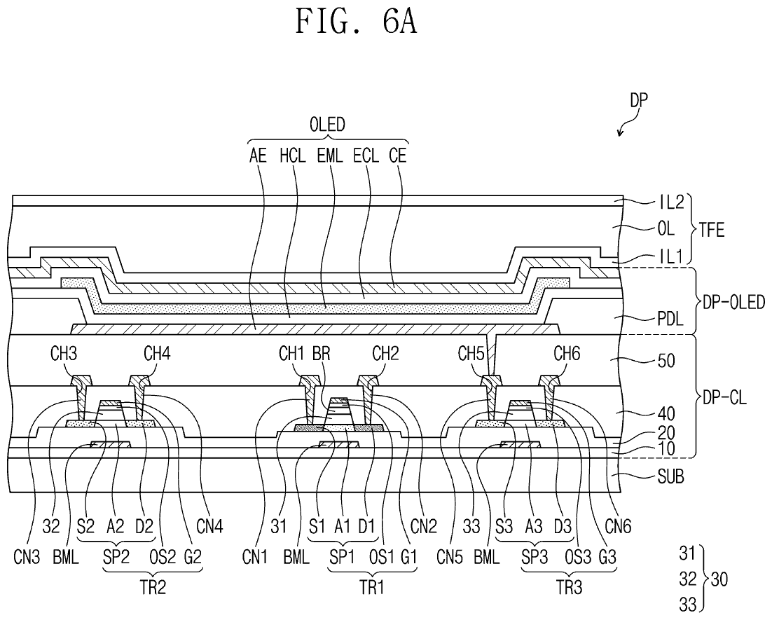

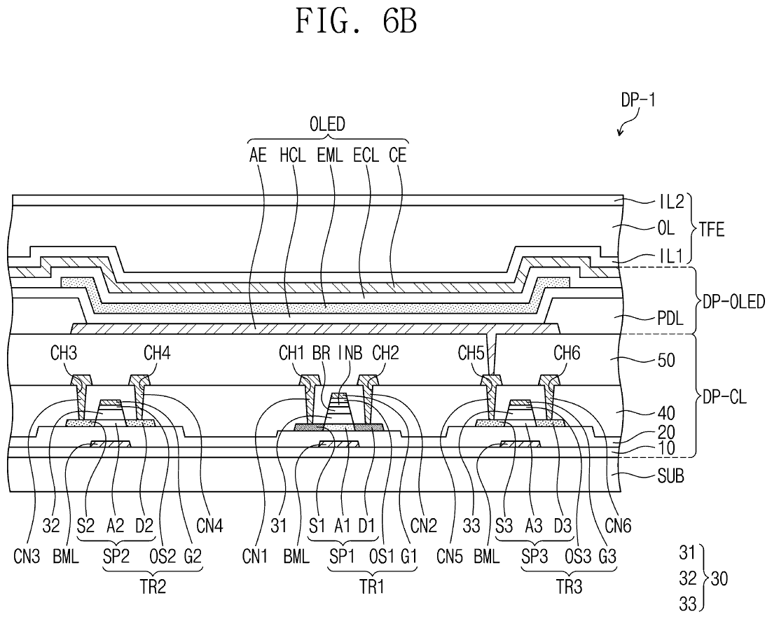

FIGS. 6A and 6B are schematic cross-sectional views of an area of display panels DP and DP-1 according to embodiments. FIGS. 6A and 6B show an area where three transistors T1, T2, and T3 and the light emitting element OLED among the components of the pixels PXij, PXij-1, and PXij-2 shown in FIGS. 5A to 5C are disposed.

Referring to FIG. 6A, the display panel DP may include the substrate SUB, the circuit element layer DP-CL, the display element layer DP-OLED, and the thin film encapsulation layer TFE.

The substrate SUB may include a glass substrate, a sapphire substrate, a plastic film, or an organic/inorganic stacked-film. The substrate SUB may have a single-layer or multi-layer structure. As an example, the substrate SUB may include a stack structure of multiple plastic films attached to each other by an adhesive or a stack structure of a glass substrate and a plastic film attached to the glass substrate by an adhesive. The substrate SUB may have flexibility. As an example, the substrate SUB may include polyimide (PI), however, this is an example. According to an embodiment, the substrate SUB may be a rigid substrate, but embodiments are not limited thereto.

The circuit element layer DP-CL may be disposed on the substrate SUB. The circuit element layer DP-CL may include a driving element and insulating layers 10, 20, 30, 40, and 50. The three transistors T1, T2, and T3 may form the circuit element layer DP-CL. The insulating layers 10, 20, 30, 40, and 50 may include first, second, third, fourth, and fifth insulating layers 10, 20, 30, 40, and 50 sequentially stacked on the substrate SUB, however, this is an example. According to an embodiment, the number of insulating layers required to form the circuit element layer DP-CL may be changed in various ways, and embodiments are not limited thereto.

The three transistors TR1, TR2, and TR3 may be disposed on the substrate SUB. The three transistors TR1, TR2, and TR3 may include a first driving element TR1, a second driving element TR2, and a third driving element TR3. The first driving element TR1, the second driving element TR2, and the third driving element TR3 may be referred to as a first thin film transistor TR1, a second thin film transistor TR2, and a third thin film transistor TR3, respectively. The first thin film transistor TR1 may function as the driving transistor, and the second and third thin film transistors TR2 and TR3 may function as the switching transistor.

In an embodiment, a lower shielding layer BML and the first and second insulating layers 10 and 20 may be disposed between the substrate SUB and the three transistors TR1, TR2, and TR3.

The lower shielding layer BML may be disposed on the first insulating layer 10. The lower shielding layer BML may shield a light traveling to the first thin film transistor TR1 from a lower side of the first thin film transistor TR1. The lower shielding layer BML may be a light shielding pattern and may include a black matrix or a reflective conductive material. In case that the lower shielding layer BML includes the conductive material, the lower shielding layer BML may be electrically floated or may be connected to the first thin film transistor TR1.

The first insulating layer 10 may be disposed on the substrate SUB and may cover (e.g., entirely cover) an upper surface of the substrate SUB. The first insulating layer 10 may include a barrier layer. For example, the first insulating layer 10 may prevent oxygen or moisture introduced through the substrate SUB from entering the pixel PXij.

The second insulating layer 20 may be disposed on the first insulating layer 10 and may cover the lower shielding layer BML. The second insulating layer 20 may cover (e.g., entirely cover) the substrate SUB. The second insulating layer 20 may include a buffer layer. For example, the second insulating layer 20 may reduce a surface energy of a surface where the circuit element layer DP-CL is formed to allow the pixel PXij to be stably formed on the substrate SUB. The buffer layer may include at least one inorganic layer. As an example, the buffer layer may include at least one of aluminum oxide, titanium oxide, silicon oxide, silicon nitride, silicon oxynitride, zirconium oxide, and hafnium oxide.

At least one of the barrier layer and the buffer layer may be provided in plural or may be omitted. For example, according to the display panel DP, the first insulating layer 10 and/or second insulating layer 20 may be omitted, but embodiments are not limited thereto.

The first thin film transistor TR1 may include a first-first semiconductor pattern SP1 and a first gate G1. The first thin film transistor TR1 may be the driving transistor disposed on a current path between the first power line PL1 and the light emitting element OLED to control the amount of current Id flowing through the light emitting element OLED.

In an embodiment, the first-first semiconductor pattern SP1 may include an oxide semiconductor. The first-first semiconductor pattern SP1 may include a metal oxide semiconductor material. The metal oxide semiconductor material may be either a crystalline or amorphous oxide semiconductor. As an example, the first-first semiconductor pattern SP1 may include the metal oxide of metals, such as zinc (Zn), indium (In), gallium (Ga), tin (Sn), titanium (Ti), etc., or a mixture of the metal, such as zinc (Zn), indium (In), gallium (Ga), tin (Sn), titanium (Ti), etc., and oxides thereof. The metal oxide semiconductor material may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), zinc-tin oxide (ZTO), or the like.

The first-first semiconductor pattern SP1 may include multiple areas with different electrical properties. As an example, the first-first semiconductor pattern SP1 may include multiple areas distinguished from each other depending on whether the metal oxide is reduced or not. The first-first semiconductor pattern SP1 may include a first source S1, a first drain D1, and a first channel A1, which are distinguished from each other depending on conductivity. For example, the first channel A1 may be an area with a relatively low conductivity compared to the first source S1 and the first drain D1 and with semiconductor properties. Each of the first source S1 and the first drain D1 may be an area with a relatively high conductivity compared to the first channel A1 and with conductive properties. The first channel A1 may be referred to as a first active A1.

Each of the first source S1 and the first drain D1 may be formed through a doping process or a reduction process. As an example, a high-doped area of the semiconductor pattern, which has a relatively high dopant concentration, may have high conductivity. Some areas of the semiconductor pattern may be doped to form the source/drain, and a remaining area may become the channel. Dopants may be p-type dopants or n-type dopants. However, embodiments are not limited thereto.

According to an embodiment, the reduced area of the oxide semiconductor pattern may have a conductivity higher than that of the non-reduced area. Since the metal oxide that constitutes the oxide semiconductor pattern is precipitated into a metal through a reduction process, the area where the metal oxide is reduced may form the source/drain, and a remaining area may become the channel.

In an embodiment, the first source S1 and the first drain D1 may be formed in the first-first semiconductor pattern SP1, however, this is an example. According to an embodiment, the source/drain of the first thin film transistor TR1 may be formed as a separate conductive pattern connected to the first-first semiconductor pattern SP1, however, embodiments are not limited thereto or thereby.

The first gate G1 may be disposed on the semiconductor pattern of the first thin film transistor TR1. The first gate G1 may overlap the first channel A1. A first insulating pattern 31 may be disposed between the first gate G1 and the semiconductor pattern. The first insulating pattern 31 may be patterned to have a shape aligned with the first gate G1.

A second-first semiconductor pattern OS1 may be disposed between the first insulating pattern 31 and the first gate G1. The second-first semiconductor pattern OS1 may be disposed under (e.g., directly under) the first gate G1. The second-first semiconductor pattern OS1 and the first-first semiconductor pattern SP1 may include the same material. The second-first semiconductor pattern OS1 may have an oxygen content greater than an oxygen content of the first-first semiconductor pattern SP1.

A barrier BR may be disposed between the first insulating pattern 31 and the second-first semiconductor pattern OS1. The barrier BR may be disposed on (e.g., directly on) the first insulating pattern 31. The barrier BR may be disposed under (e.g., directly under) the second-first semiconductor pattern OS1. The barrier BR may prevent oxygen of the second-first semiconductor pattern OS1 from entering the first-first semiconductor pattern SP1.

The barrier BR may be a metal layer. As an example, the barrier BR may include at least one of titanium (Ti), molybdenum (Mo), aluminum (Al), copper (Cu), tungsten (W), tantalum (Ta), and alloys thereof. The barrier BR may have a single-layer or multi-layer structure.

The second thin film transistor TR2 may include a second gate G2 and a first-second semiconductor pattern SP2. The second thin film transistor TR2 may be the initialization transistor T4 (refer to FIG. 5A) that is turned on in response to the initialization scan line GILi and applies the first initialization voltage VINT provided thereto through the first initialization line VIL1 to the pixel circuit as shown in FIG. 5A, however, embodiments are not limited thereto or thereby.

The first-second semiconductor pattern SP2 and the first-first semiconductor pattern SP1 may be at the same layer and may be formed as the same layer. The first-second semiconductor pattern SP2 may include an oxide semiconductor. The first-second semiconductor pattern SP2 may include a metal oxide semiconductor material. The metal oxide semiconductor material may be either a crystalline or amorphous oxide semiconductor. As an example, the first-second semiconductor pattern SP2 may include the metal oxide of metals, such as zinc (Zn), indium (In), gallium (Ga), tin (Sn), titanium (Ti), etc., or a mixture of the metal, such as zinc (Zn), indium (In), gallium (Ga), tin (Sn), titanium (Ti), etc., and oxides thereof. The metal oxide semiconductor material may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), zinc-tin oxide (ZTO), or the like.

The first-second semiconductor pattern SP2 may include multiple areas with different electrical properties. As an example, the first-second semiconductor pattern SP2 may include multiple areas distinguished from each other depending on whether the metal oxide is reduced or not. The first-second semiconductor pattern SP2 may include a second source S2, a second drain D2, and a second channel A2, which are distinguished from each other depending on conductivity. For example, the second channel A2 may be an area with a relatively low conductivity compared to the second source S2 and the second drain D2 and with semiconductor properties. Each of the second source S2 and the second drain D2 may be an area with a relatively high conductivity compared to the second channel A2 and with conductive properties. The second channel A2 may be referred to as a second active A2.

Each of the second source S2 and the second drain D2 may be formed through a doping process or a reduction process. As an example, a high-doped area of the semiconductor pattern, which has a relatively high dopant concentration, may have high conductivity. Some areas of the semiconductor pattern may be doped to form the source/drain, and a remaining area may become a channel. Dopants may be p-type dopants or n-type dopants, however, embodiments are not limited thereto.

According to an embodiment, the reduced area of the oxide semiconductor pattern may have a conductivity higher than that of the non-reduced area. Since the metal oxide that constitutes the oxide semiconductor pattern is precipitated into a metal through a reduction process, the area where the metal oxide is reduced may form the source/drain, and a remaining area may become the channel.

In an embodiment, the second source S2 and the second drain D2 may be formed in the first-second semiconductor pattern SP2, however, this is an example. According to an embodiment, the source/drain of the second thin film transistor TR2 may be formed as a separate conductive pattern connected to the first-second semiconductor pattern SP2, however, embodiments are not limited thereto or thereby.

The second gate G2 may be disposed on the semiconductor pattern of the second thin film transistor TR2. The second gate G2 may overlap the second channel A2. A second insulating pattern 32 may be disposed between the second gate G2 and the semiconductor pattern. The second insulating pattern 32 may be patterned to have a shape aligned with the second gate G2.

A second-second semiconductor pattern OS2 may be disposed between the second insulating pattern 32 and the second gate G2. The second-second semiconductor pattern OS2 may be disposed under (e.g., directly under) the second gate G2. The second-second semiconductor pattern OS2 may be disposed on (e.g., directly on) the second insulating pattern 32. The second-second semiconductor pattern OS2 and the first-second semiconductor pattern SP2 may include the same material. The second-second semiconductor pattern OS2 may have an oxygen content greater than an oxygen content of the first-second semiconductor pattern SP2. The second-second semiconductor pattern OS2 may supply oxygen to the first-second semiconductor pattern SP2.

The third thin film transistor TR3 and the second thin film transistor TR2 may have substantially the same structure. The third thin film transistor TR3 may include a third gate G3 and a first-third semiconductor pattern SP3. The first-third semiconductor pattern SP3, the first-first semiconductor pattern SP1, and the first-second semiconductor pattern SP2 may be at the same layer or may be formed as the same layer.

The first-third semiconductor pattern SP3 may include an oxide semiconductor. The first-third semiconductor pattern SP3 may include a metal oxide semiconductor material. The metal oxide semiconductor material may be either a crystalline or amorphous oxide semiconductor. As an example, the first-third semiconductor pattern SP3 may include the metal oxide of metals, such as zinc (Zn), indium (In), gallium (Ga), tin (Sn), titanium (Ti), etc., or a mixture of the metal, such as zinc (Zn), indium (In), gallium (Ga), tin (Sn), titanium (Ti), etc., and oxides thereof. The metal oxide semiconductor material may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), zinc-tin oxide (ZTO), or the like.

The first-third semiconductor pattern SP3 may include multiple areas with different electrical properties. As an example, the first-third semiconductor pattern SP3 may include multiple areas distinguished from each other depending on whether the metal oxide is reduced or not. The first-third semiconductor pattern SP3 may include a third source S3, a third drain D3, and a third channel A3, which are distinguished from each other depending on conductivity. For example, the third channel A3 may be an area with a relatively low conductivity compared to the third source S3 and the third drain D3 and with semiconductor properties. Each of the third source S3 and the third drain D3 may be an area with a relatively high conductivity compared to the third channel A3 and with conductive properties. The third channel A3 may be referred to as a third active A3.

Each of the third source S3 and the third drain D3 may be formed through a doping process or a reduction process. As an example, a high-doped area of the semiconductor pattern, which has a relatively high dopant concentration, may have high conductivity. Some areas of the semiconductor pattern may be doped to form the source/drain, and a remaining area may become a channel. Dopants may be p-type dopants or n-type dopants, however, embodiments are not limited thereto.

According to an embodiment, the reduced area of the oxide semiconductor pattern may have a conductivity higher than that of the non-reduced area. Since the metal oxide that constitutes the oxide semiconductor pattern is precipitated into a metal through a reduction process, the area where the metal oxide is reduced may form the source/drain, and a remaining area may become the channel.

In an embodiment, the third source S3 and the third drain D3 may be formed in the first-third semiconductor pattern SP3, however, this is an example. According to an embodiment, the source/drain of the third thin film transistor TR3 may be formed as a separate conductive pattern connected to the first-third semiconductor pattern SP3, however, embodiments are not limited thereto or thereby.

The third gate G3 may be disposed on the semiconductor pattern of the third thin film transistor TR3. The third gate G3 may overlap the third channel A3. A third insulating pattern 33 may be disposed between the third gate G3 and the semiconductor pattern. The third insulating pattern 33 may be patterned to have a shape aligned with the third gate G3. A second-third semiconductor pattern OS3 may be disposed between the third insulating pattern 33 and the third gate G3. The second-third semiconductor pattern OS3 may be disposed under (e.g., directly under) the third gate G3. The second-third semiconductor pattern OS3 may be disposed on (e.g., directly on) the third insulating pattern 33. The second-third semiconductor pattern OS3 and the first-third semiconductor pattern SP3 may include the same material. The second-third semiconductor pattern OS3 may have an oxygen content greater than an oxygen content of the first-third semiconductor pattern SP3. The second-third semiconductor pattern OS3 may supply oxygen to the first-third semiconductor pattern SP3.

The third thin film transistor TR3 may be the light emission control transistor T6 (refer to FIG. 5A) that is disposed on a current path between the first thin film transistor TR1 and the light emitting element OLED and provides a driving current applied thereto from the first thin film transistor TR1 to the light emitting element OLED in response to a signal applied thereto through the emission line EMLi (refer to FIG. 5A), however, embodiments are not limited thereto or thereby.

According to an embodiment, since the first thin film transistor TR1 that functions as the driving transistor includes the barrier BR, which allows a threshold voltage (Vth) to be located at a relatively negative (−) value, the amount of degradation under voltage or temperature stress may be reduced. For example, the reliability of the driving transistor may be ensured.

For example, since the second and third thin film transistors TR2 and TR3 that function as the switching transistors include the oxide semiconductor patterns OS2 and OS3, an oxygen concentration of the semiconductor patterns SP2 and SP3 may be controlled. Accordingly, the threshold voltage (Vth) of short channel lengths may be effectively controlled. For example, the threshold voltage (Vth) may be set at a relatively positive (+) value, and the tendency for the threshold voltage (Vth) to shift negatively (−) in short channel lengths may be reduced.

The first, second, and third insulating patterns 31, 32, and 33 may be connected to each other and may be integral with each other and may be formed as a single layer. For example, the third insulating layer 30 may be formed as a single insulating layer with a single unitary shape rather than the separated patterns 31, 32, and 33, but embodiments are not limited thereto.

The circuit element layer DP-CL may further include multiple connection electrodes CN1, CN2, CN3, CN4, CN5, and CN6. A first connection electrode CN1 may be connected to the first source S1 of the first thin film transistor TR1 through a first contact hole CH1, and a second connection electrode CN2 may be connected to the first drain D1 of the first thin film transistor TR1 through a second contact hole CH2. A third connection electrode CN3 may be connected to the second source S2 of the second thin film transistor TR2 through a third contact hole CH3, and a fourth connection electrode CN4 may be connected to the second drain D2 of the second thin film transistor TR2 through a fourth contact hole CH4. A fifth connection electrode CN5 may be connected to the third source S3 of the third thin film transistor TR3 through a fifth contact hole CH5, and a sixth connection electrode CN6 may be connected to the third drain D3 of the third thin film transistor TR3 through a sixth contact hole CH6.

The fifth insulating layer 50 may be disposed on the fourth insulating layer 40 and may cover the connection electrodes CN1, CN2, CN3, CN4, CN5, and CN6. The light emitting element OLED may be connected to the circuit element layer DP-CL via a contact hole formed through the fifth insulating layer 50.

In an embodiment, each of the first, second, third, fourth, and fifth insulating layers 10, 20, 30, 40, and 50 may include an inorganic layer and/or an organic layer. As an example, the first insulating layer 10 and the second insulating layer 20 may include silicon nitride and/or silicon oxide, and each of the first, second, and third insulating patterns 31, 32, and 33 forming the third insulating layer 30 may include silicon oxide. The fourth insulating layer 40 may include a silicon oxynitride layer and a silicon nitride layer, which are sequentially stacked, and the fifth insulating layer 50 may include an organic layer, however, this is an example. The material and stack structure of each of the first, second, third, fourth, and fifth insulating layers 10, 20, 30, 40, and 50 may be changed in various ways, and embodiments are not limited thereto.

The display element layer DP-OLED may be disposed on the circuit element layer DP-CL. The display element layer DP-OLED may include the light emitting element OLED and a pixel definition layer PDL. The light emitting element OLED may include a first electrode AE, a hole control layer HCL, a light emitting layer EML, an electron control layer ECL, and a second electrode CE.

The first electrode AE may be disposed on the fifth insulating layer 50. The first electrode AE may be connected to the fifth connection electrode CN5 after penetrating through the fifth insulating layer 50, however, this is an example. According to an embodiment, the first electrode AE may be connected to the third thin film transistor TR3 through a separate additional connection electrode or may be connected (e.g., directly connected) to the third source S3 of the third thin film transistor TR3.

The pixel definition layer PDL may be disposed on the fifth insulating layer 50. At least a portion of the first electrode AE may be exposed without being covered by the pixel definition layer PDL. For example, an opening may be defined through the pixel definition layer PDL to expose a portion of the first electrode AE.

The hole control layer HCL may be disposed on the first electrode AE and the pixel definition layer PDL. The hole control layer HCL may be commonly disposed over a light emitting area and a non-light-emitting area. The hole control layer HCL may include a layer having a high hole mobility to facilitate the movement of holes from the first electrode AE to the light emitting layer EML. As an example, the hole control layer HCL may include at least one of a hole transport layer, a hole injection layer, and an electron block layer, and each of the hole transport layer, the hole injection layer, and the electron block layer may have a single-layer structure or a multi-layer stack structure.

The light emitting layer EML may be disposed on the hole control layer HCL. The light emitting layer EML may be disposed in an area corresponding to the opening of the pixel definition layer PDL. The light emitting layer EML may include an organic material and/or an inorganic material. The light emitting layer EML may generate one of red light, green light, and blue light.

The electron control layer ECL may be disposed on the light emitting layer EML and the hole control layer HCL. The electron control layer ECL may be commonly disposed in the light emitting area and the non-light-emitting area. The electron control layer ECL may include a layer having a high electron mobility to facilitate the movement of electrons from the second electrode CE to the light emitting layer EML. As an example, the electron control layer ECL may include at least one of an electron transport layer, an electron injection layer, and a hole block layer, and each of the electron transport layer, the electron injection layer, and the hole block layer may have a single-layer structure or a multi-layer stack structure.

The second electrode CE may be disposed on the electron control layer ECL. The second electrode CE may be commonly disposed in the pixels PX. For example, the second electrode CE may be formed into an integral shape on the light emitting layers EML of the pixels PX, however, this is an example. According to an embodiment, the second electrode CE may also be formed as a separate pattern for each pixel PX, however, embodiments are not limited thereto or thereby. The second electrode CE may have a semi-transmissive property or a transmissive property. The second electrode CE may be formed in various forms, such as, a transparent conductive oxide layer, a thin metal layer having a transmissive property, and a layer having a stack structure of a metal layer and an oxide layer. In case that the light emitting element OLED has a rear emission structure, the second electrode CE may be a reflective electrode.

The thin film encapsulation layer TFE may be disposed on the display element layer DP-OLED. The thin film encapsulation layer TFE may include an inorganic layer and an organic layer. In an embodiment, the thin film encapsulation layer TFE may have a structure in which a first inorganic layer IL1, an organic layer OL, and a second inorganic layer IL2 are sequentially stacked, however, the stack structure of layers constituting the thin film encapsulation layer TFE may be changed in various ways.

The first inorganic layer IL1 and the second inorganic layer IL2 may include an inorganic material and may protect the pixels from moisture and oxygen. The first inorganic layer IL1 and the second inorganic layer IL2 may include the same material as each other or may include different materials from each other. The organic layer OL may include an organic material and may protect the display element layer DP-OLED or the circuit element layer DP-CL from foreign substances.

Referring to FIG. 6B, an inorganic layer INB may be further disposed on a barrier BR according to an embodiment. The inorganic layer INB may be an insulating layer. The inorganic layer INB may include an inorganic material, e.g., at least one of silicon oxide, silicon nitride, and aluminum oxide.

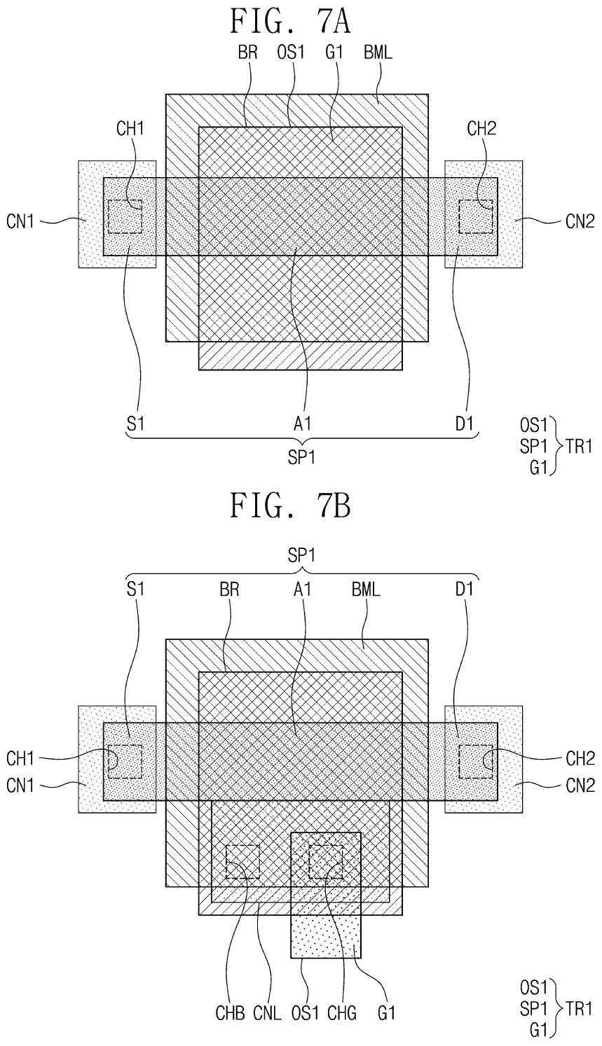

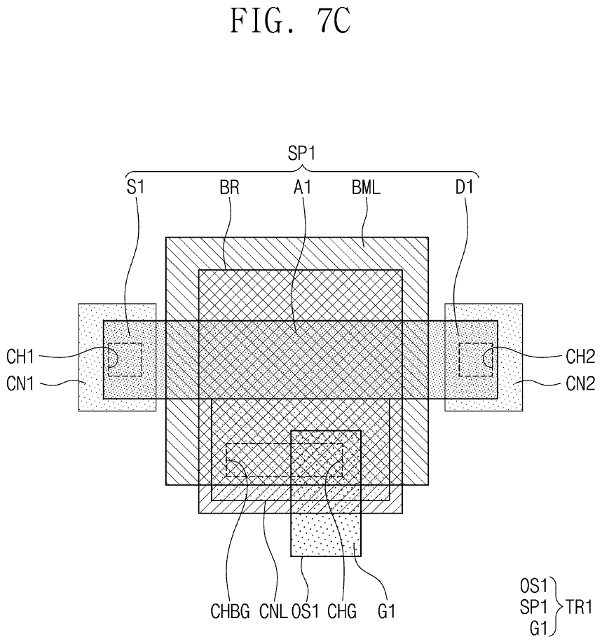

FIGS. 7A, 7B, and 7C are schematic plan views of some components of a circuit element layer according to embodiments. FIGS. 7A, 7B, and 7C show a driving transistor T1 and components around the driving transistor T1 according to embodiments.

Referring to FIG. 7A, a first gate G1, a second-first semiconductor pattern OS1, and a barrier BR may overlap each other in plan view. FIG. 7A shows a structure in which the first gate G1, the second-first semiconductor pattern OS1, and the barrier BR have substantially the same size as each other. However, embodiments are not limited thereto or thereby. According to an embodiment, the second-first semiconductor pattern OS1 may overlap the first gate G1 and may have the size larger than that of the first gate G1. For example, the barrier BR may overlap the second-first semiconductor pattern OS1 and may have the size larger than that of the second-first semiconductor pattern OS1.

In case that the second-first semiconductor pattern OS1 has a thin thickness, an ohmic contact may be formed between the barrier BR and the second-first semiconductor pattern OS1 and between the second-first semiconductor pattern OS1 and the first gate G1 even without separately connecting the barrier BR and the first gate G1. Accordingly, a charge concentration of the second-first semiconductor pattern OS1 may increase. As an example, the thickness of the second-first semiconductor pattern OS1 may be equal to or smaller than about 50 nm.

Different from the circuit element layer shown in FIG. 7A, FIGS. 7B and 7C show a structure in which a barrier BR is connected to a first gate G1. Different from the circuit element layer shown in FIG. 7A, the first gate G1 and a second-first semiconductor pattern OS1 may overlap a portion of the barrier BR in plan view.

The barrier BR may be electrically connected to the first gate G1 through contact holes CHB, CHG, and CHBG. A connection electrode CNL may function as a connection electrode to connect the barrier BR and the first gate G1. The connection electrode CNL may be disposed on the fourth insulating layer 40.

Referring to FIG. 7B, the connection electrode CNL may be connected to the barrier BR via a barrier contact hole CHB defined through the fourth insulating layer 40 and may be connected to the first gate G1 via a gate contact hole CHG defined through the fourth insulating layer 40. The barrier contact hole CHB may overlap the barrier BR in plan view and may not overlap the first gate G1 and the second-first semiconductor pattern OS1. The gate contact hole CHG may overlap each of the barrier BR, the first gate G1, and the second-first semiconductor pattern OS1.

Referring to FIG. 7C, the connection electrode CNL may be connected to each of the barrier BR and the first gate G1 via the contact hole CHBG defined through the fourth insulating layer 40. In an embodiment, the contact hole CHBG may be a through hole that extends from an area where the barrier BR is disposed and the first gate G1 and the second-first semiconductor pattern OS1 are not disposed to an area where the barrier BR, the first gate G1, and the second-first semiconductor pattern OS1 are disposed in plan view.

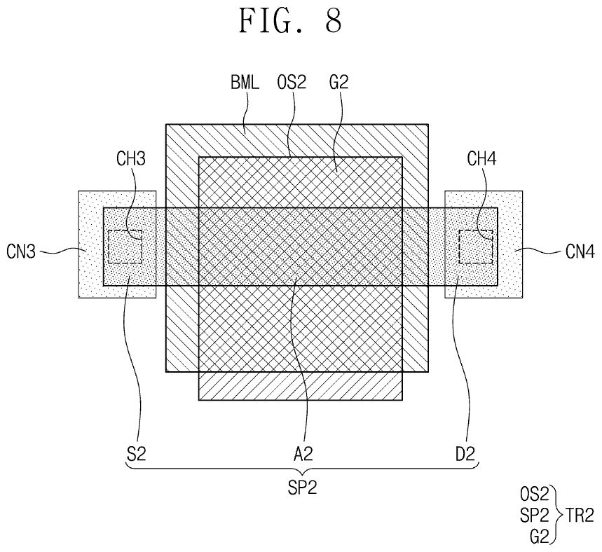

FIG. 8 is a schematic plan view of some components of a circuit element layer according to an embodiment. FIG. 8 shows a switching transistor T2 and components around the switching transistor T2 according to an embodiment.

Referring to FIG. 8, a second gate G2 may overlap a second-second semiconductor pattern OS2 in plan view. FIG. 8 shows a structure in which the second gate G2 and the second-second semiconductor pattern OS2 have substantially the same size as each other, however, embodiments are not limited thereto or thereby. According to an embodiment, the second-second semiconductor pattern OS2 may overlap the second gate G2 and may have the size larger than that of the second gate G2.

The display panel DP according to an embodiment may include the barrier BR disposed on the first insulating pattern 31 of the first thin film transistor TR1 that functions as the driving transistor and may include the oxide semiconductor patterns OS2 and OS3 disposed above the second and third insulating patterns 32 and 33 of the second and third thin film transistors TR2 and TR3 that function as the switching transistor, and thus, the thin film transistors may be designed independently according to each function thereof. Therefore, the first thin film transistor TR1 may secure (or ensure) a high driving range without deterioration, and thus, the display panel supporting representation of various grayscale levels may be provided. For example, since the second and third thin film transistors TR2 and TR3 have the high mobility and the short channel length, the leakage current in the pixel driver may be reduced.

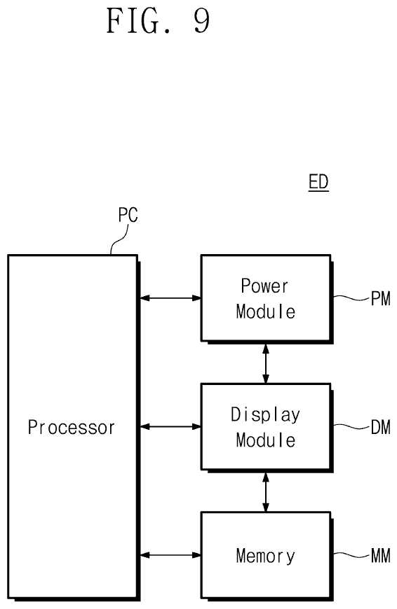

FIG. 9 is a block diagram of an electronic device ED according to an embodiment of the present disclosure.

Referring to FIG. 9, the electronic device ED may include a display module DM, a processor PC, a memory MM, and a power module PM.

The processor PC may include at least one of a central processing unit (CPU), an application processor (AP), a graphics processing unit (GPU), a communication processor (CP), an image signal processor (ISP), and a controller.

The memory MM may store data information required for the operation of the processor PC or the display module DM. When the processor PC executes an application stored in the memory MM, an image data signal and/or an input control signal may be transmitted to the display module DM, and the display module DM may process the received signals to output image information through a display screen.

The power module PM may include a power supply module, such as a power adapter or a battery device, and a power conversion module that converts power supplied by the power supply module to generate power required for the operation of the electronic device ED.

At least one of components of the electronic device ED may be included in the display device DD (refer to FIG. 1) according to embodiments. In addition, among individual modules that are functionally included within a single module, some may be included in the display device while others may be provided separately from the display device DD (refer to FIG. 1). As an example, the display device DD (refer to FIG. 1) may include the display module DM. The processor PC, the memory MM, and the power module PM may be provided as separate devices within the electronic device ED and may not be included in the display device DD (refer to FIG. 1).

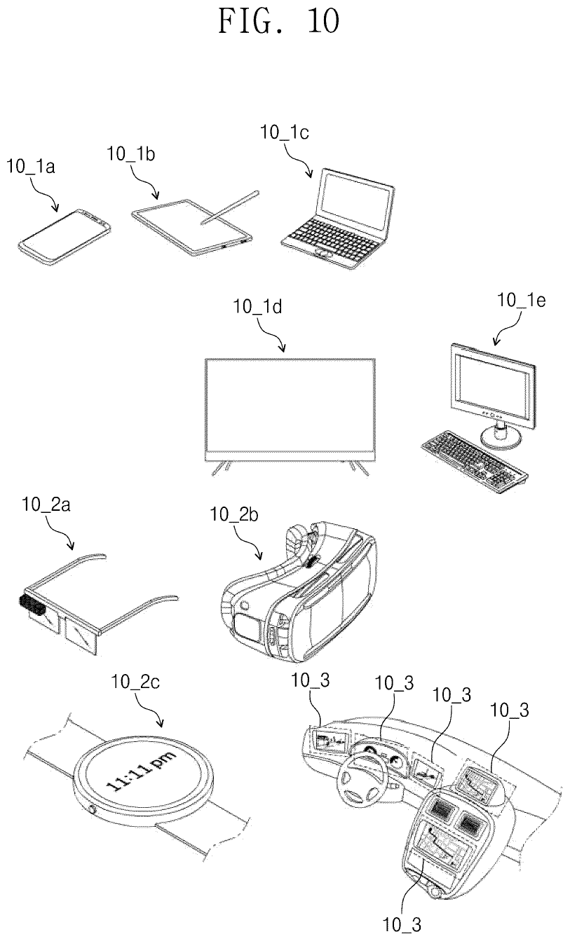

FIG. 10 is a schematic view of various electronic devices according to embodiments of the present disclosure.

Referring to FIG. 10, various electronic devices ED to which the display device DD (refer to FIG. 1) according to embodiments is applied may include an electronic device to display images, such as a smartphone 10_1a, a tablet PC 10_1b, a laptop computer 10_1c, a television 10_1d, a desktop monitor 10_1e, etc., a wearable electronic device including a display module, such as a smart glasses 10_2a, a head-mounted display 10_2b, a smartwatch 10_2c, etc., or an in-vehicle electronic device 10_3 including a display module, such as an instrument panel, a center fascia, a dashboard-mounted center information display (CID), or a room mirror display.

Although the embodiments have been described, it is understood that the disclosure should not be limited to these embodiments but various changes and modifications can be made by one ordinary skilled in the art within the spirit and scope of the disclosure as hereinafter claimed. Therefore, the disclosed subject matter should not be limited to any single embodiment described herein, and the scope of the invention shall be determined according to the attached claims.

What is claimed is:

1. A display panel comprising:
a substrate;
a light emitting element disposed on the substrate; and
a pixel driver connected to the light emitting element,
wherein the pixel driver comprising:
a first transistor comprising:
a first-first semiconductor pattern,
a second-first semiconductor pattern disposed on the first-first semiconductor pattern, and
a barrier disposed between the first-first semiconductor pattern and the second-first semiconductor pattern; and
a second transistor comprising:
a first-second semiconductor pattern, and
a second-second semiconductor pattern disposed on the first-second semiconductor pattern.

2. The display panel of claim 1, wherein
the first transistor is a driving transistor, and
the second transistor is a switching transistor.

3. The display panel of claim 1, wherein each of the first-first semiconductor pattern, the second-first semiconductor pattern, the first-second semiconductor pattern, and the second-second semiconductor pattern comprises an oxide semiconductor.

4. The display panel of claim 3, wherein
the second-first semiconductor pattern has an oxygen content greater than an oxygen content of the first-first semiconductor pattern, and
the second-second semiconductor pattern has an oxygen content greater than an oxygen content of the first-second semiconductor pattern.

5. The display panel of claim 3, wherein each of the first-first semiconductor pattern and the first-second semiconductor pattern comprises a crystalline oxide semiconductor.

6. The display panel of claim 3, wherein
each of the first-first semiconductor pattern and the first-second semiconductor pattern comprises indium atoms and gallium atoms, and
a composition ratio of the indium atoms to the gallium atoms per unit volume is about 2 or more in both the first-first semiconductor pattern and the first-second semiconductor pattern.

7. The display panel of claim 1, wherein
the first-first semiconductor pattern and the second-first semiconductor pattern have a same composition as each other, and
the first-second semiconductor pattern and the second-second semiconductor pattern have a same composition as each other.

8. The display panel of claim 1, wherein each of the first-first semiconductor pattern and the first-second semiconductor pattern has a multi-layer structure formed of different compositions.

9. The display panel of claim 1, wherein the barrier has a single-layer structure or a multi-layer structure.

10. The display panel of claim 1, wherein the barrier comprises a metal layer.

11. The display panel of claim 10, wherein the metal layer comprises at least one of titanium, molybdenum, aluminum, copper, tungsten, tantalum, and alloys thereof.

12. The display panel of claim 1, wherein
the first transistor further comprises a first gate disposed on the second-first semiconductor pattern, and
the first gate is disposed to correspond to the second-first semiconductor pattern in plan view.

13. The display panel of claim 12, wherein the second-first semiconductor pattern and the first gate are disposed to correspond to the barrier in plan view.

14. The display panel of claim 12, further comprising:
an insulating layer disposed on the first gate and a connection electrode disposed on the insulating layer,
wherein the second-first semiconductor pattern and the first gate are disposed to overlap a portion of the barrier in plan view,
the insulating layer including a first contact hole and a second contact hole and spaced apart from the first contact hole in plan view,
the first contact hole overlaps the barrier and does not overlap the second-first semiconductor pattern and the first gate in plan view,
the second contact hole overlaps the barrier, the second-first semiconductor pattern, and the first gate in plan view, and
the connection electrode is connected to the barrier through the first contact hole and connected to the first gate through the second contact hole.

15. The display panel of claim 12, further comprising:
an insulating layer disposed on the first gate and a connection electrode disposed on the insulating layer,
wherein the second-first semiconductor pattern and the first gate are disposed to overlap a portion of the barrier in plan view,
the insulating layer including a contact hole,
a portion of the contact hole overlaps the barrier and does not overlap the second-first semiconductor pattern and the first gate in plan view,
another portion of the contact hole overlaps the barrier, the second-first semiconductor pattern, and the first gate in plan view, and
the connection electrode is connected to the barrier and the first gate through the contact hole.

16. The display panel of claim 1, further comprising:
an inorganic insulating layer disposed on the barrier.

17. The display panel of claim 16, wherein the inorganic insulating layer comprises at least one of silicon oxide, silicon nitride, and aluminum oxide.

18. The display panel of claim 1, wherein
the second transistor further comprises a second gate disposed on the second-second semiconductor pattern, and
the second gate is disposed to correspond to the second-second semiconductor pattern in plan view.

19. An electronic device comprising:
a substrate;
a light emitting element disposed on the substrate; and
a pixel driver connected to the light emitting element,
wherein the pixel driver comprising:
a first transistor comprising a first-first semiconductor pattern, a first insulating layer, a barrier comprising at least one metal layer, a second-first semiconductor pattern, and a first gate, which are sequentially stacked, and
each of the first-first semiconductor pattern and the second-first semiconductor pattern comprises an oxide semiconductor.

20. The electronic device of claim 19, wherein
the pixel driver further comprises a second transistor comprising a first-second semiconductor pattern, a second insulating layer, a second-second semiconductor pattern, and a second gate, which are sequentially stacked, and
each of the first-second semiconductor pattern and the second-second semiconductor pattern comprises an oxide semiconductor.
